(19) United States
(12) Patent Application Publication
(10) Pub. No.: US 2007/0119700 A1
(43) Pub. Date: May 31, 2007

(54) APPARATUS AND METHOD FOR MANUFACTURING A MULTILAYER FILM

(75) Inventor: GA-LANE CHEN, Santa Clara, CA (US)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,489

(22) Filed: Aug. 11, 2006

(30) Foreign Application Priority Data
Nov. 25, 2005 (TW) 94141528

(51) Int. Cl. C23C 14/32; C23C 14/00

(52) U.S. Cl. 204/192.1; 204/298.25

(57) ABSTRACT

An exemplary apparatus for manufacturing a multilayer film includes a sputtering system. The sputtering system includes a first sputtering chamber, a nitrogen-doping sputtering chamber, a nitrogen and hydrogen-doping sputtering chamber, and a hydrogen-doping sputtering chamber connected to each other in that order. The first sputtering chamber is configured with two targets and at least one inert gas. The nitrogen-doping sputtering chamber is configured with a carbon-doped target and at least one inert gas. The nitrogen and hydrogen-doping sputtering chamber is configured with a carbon-doped target and at least one inert gas. The hydrogen-doping sputtering chamber formed configured with a carbon-doped target and at least one inert gas. Adjacent sputtering chambers have at least a valve configured. A related method for manufacturing a multilayer film is also provided.

### TECHNICAL FIELD

The present invention relates to apparatuses and methods for manufacturing a multilayer film; and more particularly to an apparatus for manufacturing a multilayer film having good wear resistance and stable chemical and mechanical characteristics, and a method for manufacturing the multilayer film.

### BACKGROUND

Diamond-like carbon films have similar characteristics to diamond, such as high hardness, a low friction coefficient, and high chemical stability. Therefore diamond-like carbon films are used in equipment such as molds, where the diamond-like carbon film serves as a protection layer to improve corrosion resistance and wear resistance. A diamond-like carbon film formed on a mold is generally a single layer created by a direct current sputtering process. This kind of diamond-like carbon film commonly has poor wear resistance. When the mold is repeatedly used many times, the diamond-like carbon film may easily detach or even peel off from the base surface of the mold. When this happens, the mold has lower corrosion resistance and reduced wear resistance.

What is needed, therefore, is an apparatus for manufacturing a multilayer film that has good wear resistance and stable chemical and mechanical characteristics. What is also needed is a method for manufacturing the multilayer film.

### SUMMARY

In one embodiment, an apparatus for manufacturing a multilayer film includes a sputtering system. The sputtering system includes a first sputtering chamber, a nitrogen-doping sputtering chamber, a nitrogen and hydrogen-doping sputtering chamber, and a hydrogen-doping sputtering chamber connected to each other in that order. The first sputtering chamber is configured with two targets and at least one inert gas. The nitrogen-doping sputtering chamber is configured with a carbon-doped target and at least one inert gas. The nitrogen and hydrogen-doping sputtering chamber is configured with a carbon-doped target and at least one inert gas. The hydrogen-doping sputtering chamber is configured with a carbon-doped target and at least one inert gas. Adjacent sputtering chambers have at least one valve configured therebetween.

In another embodiment, a method for manufacturing a multilayer film includes: providing a substrate; forming a nanometer adhesive layer on surface of the substrate by an alternating current magnetron sputtering method; forming a nanometer intermediate layer on the adhesive layer by an alternating current magnetron sputtering method; forming a nitrogen-doped diamond-like carbon layer on the intermediate layer by an alternating current magnetron sputtering method; forming a nitrogen and hydrogen-doped diamond-like carbon layer on the nitrogen-doped diamond-like carbon layer by an alternating current magnetron sputtering method; and forming a hydrogen-doped diamond-like carbon layer on the nitrogen and hydrogen-doped diamond-like carbon by an alternating current magnetron sputtering method.

Other advantages and novel features will become more apparent from the following detailed description of various embodiments of the present apparatus and method for manufacturing a multilayer film when taken in conjunction with the accompanying drawings.

### BRIEF DESCRIPTION OF THE DRAWINGS

The components in the drawings are not necessarily drawn to scale, the emphasis instead being placed upon clearly illustrating the principles of the present apparatus and method. Moreover, in the drawings, like reference numerals designate corresponding parts throughout the several views.

FIG. 1 is a schematic, side cross-sectional view of an article that includes a multilayer film formed on a substrate in accordance with embodiments of the present invention.

FIG. 2 is a schematic diagram of an apparatus for manufacturing the film on the substrate shown in FIG. 1, in accordance with a first embodiment of the present invention.

FIG. 3 is a schematic view of another apparatus for manufacturing the film on the substrate shown in FIG. 1, in accordance with a second embodiment of the present invention.

FIG. 4 is a flowchart of a method for manufacturing a film on a substrate such as the film on the substrate shown in FIG. 1, in accordance with a third embodiment of the present invention.

### DETAILED DESCRIPTION OF EMBODIMENTS

Reference will now be made to the drawing figures to describe in detail preferred embodiments of the present apparatus and method for manufacturing a multilayer film.

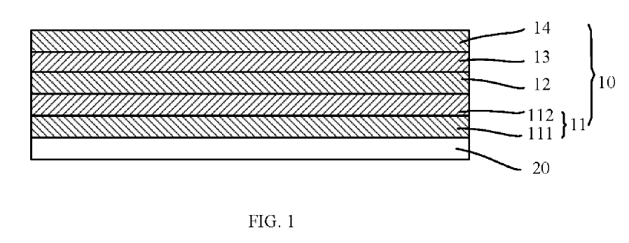

Referring to FIG. 1, an article 1 with a multilayer film 10 formed in accordance with embodiments of the present invention is shown. The article 1 includes a substrate 20, and the film 10 formed on the substrate 20. The film 10 includes a transition layer 11, a nitrogen-doped diamond-like carbon layer 12, a nitrogen and hydrogen-doped diamond-like carbon layer 13, and a hydrogen-doped diamond-like carbon layer 14 stacked in that order from bottom to top. The transition layer 11 includes an adhesive layer 111 and an intermediate layer 112.

The substrate 20 can for example be a precursor base of a mold. In other examples, a variety of equipment or products may include the substrate 20 having the film 10 formed thereon. A material of the adhesive layer 111 is selected from the group consisting of chrome, titanium, and chrome titanium. A thickness of the adhesive layer 111 is in the range from 1 nanometer to 20 nanometers. A material of the intermediate layer 112 is selected from the group consisting of chromium nitride, titanium nitride, and a mixture thereof. A thickness of the intermediate layer 112 is in the range from 1 nanometer to 50 nanometers.

The nitrogen-doped diamond-like carbon layer 12 has stable chemical and mechanical characteristics. The hydrogen-doped diamond-like carbon layer 14 has a low friction coefficient and good wear resistance. The film 10 resists detachment or peeling off from the substrate 20 because of the adhesive layer 111.

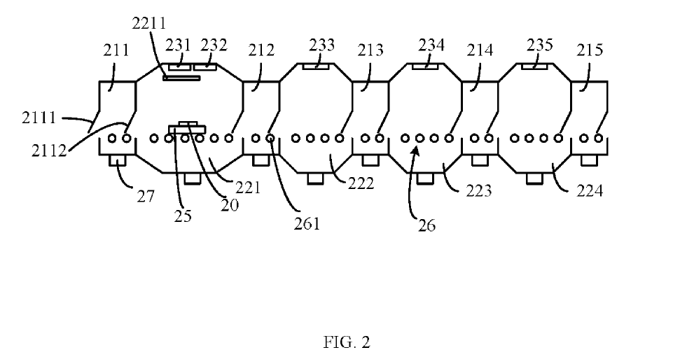

Referring to FIG. 2, an apparatus 200 for manufacturing the film 10 in accordance with a first embodiment of the present invention is shown. The apparatus 200 includes a sputtering system and a transmission system 26.

The sputtering system includes a first vacuum chamber 211, a second vacuum chamber 212, a third vacuum chamber 213, a fourth vacuum chamber 214, and a fifth vacuum chamber 215 connected to each other in that order. A respective sputtering chamber (see below) is configured between each two adjacent of the vacuum chambers 211˜215. A vacuum pump 27 is provided with each sputtering chamber.

A first sputtering chamber 221 is configured between the first vacuum chamber 211 and the second vacuum chamber 212, and is used to sputter the transition layer 11. A first target 231 is provided in the first sputtering chamber 221 for sputtering the adhesive layer 111, and a second target 232 is provided in the first sputtering chamber 221 for sputtering the intermediate layer 112. A blocking plate 2211 is provided in the first sputtering chamber 221 for selectively blocking the first target 231 or the second target 232. A material of the first target 231 is selected from the group consisting of chrome, titanium, and chrome titanium. A material of the second target 232 is selected from the group consisting of chromium nitride, titanium nitride, and a mixture thereof.

At least one valve is configured between the first sputtering chamber 221 and each adjacent vacuum chamber 211, 212. During a sputtering process carried out in the first sputtering chamber 221, each vacuum chamber 211, 212 is utilized as a buffer. The first vacuum chamber 211 has two valves 2111, 2112. When the valve 2111 is open, the vacuum chamber 211 is open to an outside of the apparatus 200. When the valve 2112 is open, the vacuum chamber 211 is open to the first sputtering chamber 221.

The first sputtering chamber 221 contains at least one inert gas therein. The at least one inert gas is selected from the group consisting of argon gas and krypton gas.

A nitrogen-doping sputtering chamber 222 having a carbon-doped target 233 therein is configured between the second vacuum chamber 212 and the third vacuum chamber 213. The sputtering chamber 222 contains nitrogen gas in the range from 2% to 40% by volume.

A nitrogen and hydrogen-doping sputtering chamber 223 having a carbon-doped target 234 therein is configured between the third vacuum chamber 213 and the fourth vacuum chamber 214. The sputtering chamber 223 contains nitrogen gas in the range from 2% to 10% by volume, and a gas containing the element hydrogen. The gas containing the element hydrogen is present in the range from 5% to 15% by volume, and is selected from the group consisting of hydrogen gas, methane, and ethane.

A hydrogen-doping sputtering chamber 224 having a carbon-doped target 235 therein is configured between the fourth vacuum chamber 214 and the fifth vacuum chamber 215. The sputtering chamber 224 contains a gas containing the element hydrogen. The gas containing the element hydrogen is present in the range from 5% to 20% by volume, and is selected from the group consisting of hydrogen gas, methane, and ethane.

As with the first sputtering chamber 221, at least one valve is configured between each sputtering chamber 222, 223, 224 and each respective adjacent of the vacuum chambers 212, 213, 214, 215. As with the first sputtering chamber 221, each sputtering chamber 222, 223, 224 contains at least one inert gas therein. The at least one inert gas is selected from the group consisting of argon gas and krypton gas.

A pressure within each sputtering chamber 221˜224 is equal to or less than 10 pascal. A material of the carbon-doped targets 233, 234, 235 is selected from the group consisting of graphite and carbon.

The transmission system 26 is used to move a carrier 25 therealong. The carrier 25 is for holding the substrate 20. The substrate 20 is put onto the carrier 25. Thus the transmission system 26 can move the substrate 20 along through the first vacuum chamber 211, the first sputtering chamber 221, and so on through to the fifth vacuum chamber 215 of the sputtering system as required, and then take the substrate 20 out from the sputtering system. In this first embodiment, the transmission system 26 includes a number of rollers 261 configured for moving the carrier 25 along a same direction. The transmission system 26 can further or alternatively include a transmission belt.

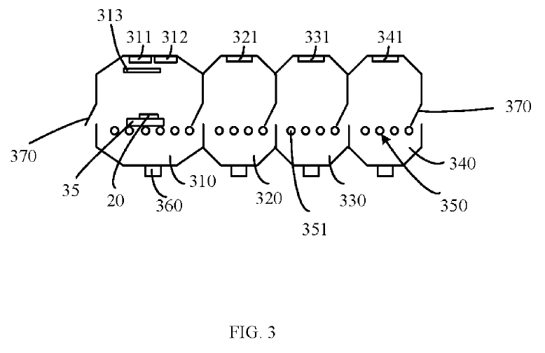

Referring to FIG. 3, another apparatus 300 for manufacturing the film 10 in accordance with a second embodiment of the present invention is shown. The apparatus 300 includes four sputtering chambers 310, 320, 330, 340 connected to each other in that order.

Each two adjacent of the sputtering chambers 310˜340 are interconnected via at least one respective valve 370. The sputtering chamber 310 is open to an outside of the apparatus 300 through at least another valve 370, and the sputtering chamber 340 is open to an outside of the apparatus 300 through at least still another valve 370. The sputtering chamber 310 is used to sputter the transition layer 11. The sputtering chamber 310 has a first target 311 and a second target 312 therein. The first target 311 is used to sputter the adhesive layer 111, and the second target 312 is used to sputter the intermediate layer 112. The sputtering chamber 310 has a blocking plate 313 therein, for selectively blocking the first target 311 or the second target 312.

The sputtering chamber 320 has a carbon-doped target 321 and nitrogen gas therein, and is used to sputter the nitrogen-doped diamond-like carbon layer 12. The sputtering chamber 330 has a carbon-doped target 331 and nitrogen gas and gas containing the element hydrogen therein, and is used to sputter the nitrogen and hydrogen-doped diamond-like carbon layer 13. The sputtering chamber 340 has a carbon-doped target 341 and gas containing the element hydrogen therein, and is used to sputter the hydrogen-doped diamond-like carbon layer 14.

Each sputtering chamber 310˜340 also has a vacuum pump 360 for evacuating the sputtering chamber 310˜340. The apparatus 300 further includes a transmission system 350, which is used to move a carrier 35 therealong. The carrier 35 is for holding the substrate 20. The substrate 20 is put onto the carrier 35. Thus the transmission system 350 can move the substrate 20 along through the sputtering chambers 310˜340 as required, and then take the substrate 20 out from the sputtering chamber 340. In this second embodiment, the transmission system 350 includes a number of rollers 351 configured for moving the carrier 35 along a same direction. The transmission system 350 can further or alternatively include a transmission belt.

In an alternative embodiment, the targets 311, 312 can be configured in two separate sputtering chambers, instead of the one sputtering chamber 310.

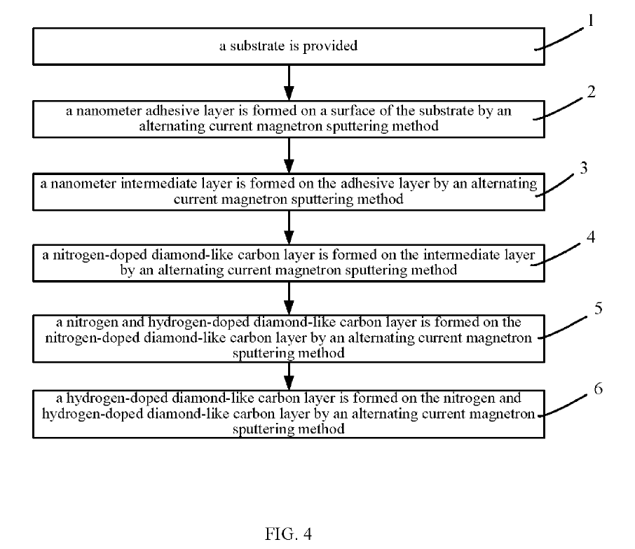

Referring to FIG. 4, a method for manufacturing a film such as the film 10 using the apparatus 300 in accordance with a third embodiment of the present invention is shown. The method is described in detailed as follows:

In step 1, a substrate such as the substrate 20 is provided. The substrate 20 can for example be a precursor base of a mold. In other examples, a variety of equipment or product precursors may include the substrate 20 for having the film 10 formed thereon.

In step 2, a nanometer adhesive layer such as the adhesive layer 111 is formed on a surface of the substrate 20 by an alternating current magnetron sputtering method. The end valve 370 of the sputtering chamber 310 is opened, and the substrate 20 is put onto the transmission system 350. The end valve 370 of the sputtering chamber 310 and the valve 370 between the sputtering chamber 310 and the sputtering chamber 320 are closed. During the sputtering process, the substrate 20 is functions as an anode and the first target 311 functions as a cathode. An alternating current is applied between the anode and the cathode. Therefore, the inert gas in the sputtering chamber 310 is ionized. Inert gas ions strike the first target 311, and atoms of the first target 311 are deposited on the substrate 20. The blocking plate 313 blocks the second target 312 when the adhesive layer 111 is being sputtered.

In step 3, a nanometer intermediate layer such as the intermediate layer 112 is formed on the adhesive layer 111 by an alternating current magnetron sputtering method that is similar to the alternating current magnetron sputtering method of step 2. The blocking plate 313 blocks the first target 311, and then the intermediate layer 112 is formed by sputtering the second target 312. The valve 370 between the sputtering chambers 310, 320 is opened, and the substrate is moved into the sputtering chamber 320 by the transmission system 350.

In step 4, a nitrogen-doped diamond-like carbon layer such as the nitrogen-doped diamond-like carbon layer 12 is formed on the intermediate layer 112 by an alternating current magnetron sputtering method that is similar to the alternating current magnetron sputtering method of steps 2 or 3. In the sputtering chamber 320, a reactive alternating current sputtering process takes place. The nitrogen gas chemically reacts with the target 321, and nitrogen-doped matter is generated. The nitrogen-doped matter is deposited on the intermediate layer 112 as nitrogen-doped diamond-like carbon. The valve 370 between the sputtering chambers 320, 330 is opened, and the substrate 20 is moved into the sputtering chamber 330 by the transmission system 350.

In step 5, a nitrogen and hydrogen-doped diamond-like carbon layer such as the nitrogen and hydrogen-doped diamond-like carbon layer 13 is formed on the nitrogen-doped diamond-like carbon layer 12 by an alternating current magnetron sputtering method that is similar to the alternating current magnetron sputtering method of step 4. In the sputtering chamber 330, a reactive alternating current sputtering process takes place. Nitrogen gas and gas containing the element hydrogen chemically react with the target 331, and nitrogen-doped matter and hydrogen-doped matter are generated. The nitrogen-doped matter and hydrogen-doped matter are deposited on the nitrogen-doped diamond-like carbon layer 12 as nitrogen and hydrogen-doped diamond-like carbon. The valve 370 between the sputtering chambers 330, 340 is opened, and the substrate 20 is moved into the sputtering chamber 340 by the transmission system 350.

In step 6, a hydrogen-doped diamond-like carbon layer such as the hydrogen-doped diamond-like carbon layer 14 is formed on the nitrogen and hydrogen-doped diamond-like carbon layer 13 by an alternating current magnetron sputtering method that is similar to the alternating current magnetron sputtering method of steps 4 or 5. In the sputtering chamber 340, a reactive alternating current sputtering process takes place. Gas containing the element hydrogen chemically reacts with the target 341, and hydrogen-doped matter is generated. The hydrogen-doped matter is deposited on the nitrogen and hydrogen-doped diamond-like carbon layer 13 as hydrogen-doped diamond-like carbon. The valve 370 of the sputtering chamber 340 is opened, and the substrate 20 is taken out of the apparatus 300. Thus, the film 10 formed on the substrate 20 is obtained.

Although the present invention has been described with reference to specific embodiments, it should be noted that the described embodiments are not necessarily exclusive, and that various changes and modifications may be made to the described embodiments without departing from the scope of the invention as defined by the appended claims and equivalents thereof.

What is claimed is:

1. An apparatus for manufacturing a multilayer film, the apparatus comprising a sputtering system, the sputtering system comprising:
a first sputtering chamber, a nitrogen-doping sputtering chamber, a nitrogen and hydrogen-doping sputtering chamber, and a hydrogen-doping sputtering chamber connected to each other in that order, the first sputtering chamber being configured with two targets and at least one inert gas, the nitrogen-doping sputtering chamber being configured with a carbon-doped target and at least one inert gas, the nitrogen and hydrogen-doping sputtering chamber being configured with a carbon-doped target and at least one inert gas, and the hydrogen-doping sputtering chamber being configured with a carbon-doped target and at least one inert gas; and
at least one valve configured between each two adjacent sputtering chambers.

2. The apparatus as claimed in claim 1, further comprising a first vacuum chamber configured between the first sputtering chamber and an outside of the apparatus, a second vacuum chamber configured between the first sputtering chamber and the nitrogen-doping sputtering chamber, a third vacuum chamber configured between the nitrogen-doping sputtering chamber and the nitrogen and hydrogen-doping sputtering chamber, a fourth vacuum chamber configured between the nitrogen and hydrogen-doping sputtering chamber and the hydrogen-doping sputtering chamber, and a fifth vacuum chamber configured between the hydrogen-doping sputtering chamber and an outside of the apparatus.

3. The apparatus as claimed in claim 1, wherein a material of one of the two targets in the first sputtering chamber is selected from the group consisting of chrome, titanium, and chrome titanium.

4. The apparatus as claimed in claim 3, wherein a material of the other of the two targets in the first sputtering chamber is selected from the group consisting of chromium nitride, titanium nitride, and a mixture thereof.

5. The apparatus as claimed in claim 1, wherein a material of each of the carbon-doped targets is selected from the group consisting of graphite and carbon.

6. The apparatus as claimed in claim 1, wherein the nitrogen-doping sputtering chamber comprises nitrogen gas in the range from 2% to 40% by volume.

7. The apparatus as claimed in claim 1, wherein the nitrogen and hydrogen-doping sputtering chamber comprises nitrogen gas in the range from 2% to 10% by volume, and gas containing the element hydrogen in the range from 5% to 15% by volume.

8. The apparatus as claimed in claim 1, wherein the hydrogen-doping sputtering chamber comprises gas containing the element hydrogen in the range from 5% to 20% by volume.

9. The apparatus as claimed in claim 7, wherein the gas containing the element hydrogen is selected from the group consisting of hydrogen gas, methane, and ethane.

10. The apparatus as claimed in claim 8, wherein the gas containing the element hydrogen is selected from the group consisting of hydrogen gas, methane, and ethane.

11. The apparatus as claimed in claim 1, wherein the at least one inert gas is selected from the group consisting of argon gas and krypton gas.

12. The apparatus as claimed in claim 1, further comprising a transmission system configured for transmitting an object along through the sputtering system, the object being provided for having a multilayer film formed thereon.

13. The apparatus as claimed in claim 12, wherein the transmission system comprises a plurality of rollers configured to rotate in a same direction.

14. A method for manufacturing a multilayer film, comprising:
providing a substrate;
forming a nanometer adhesive layer on a surface of the substrate by an alternating current magnetron sputtering method;
forming a nanometer intermediate layer on the adhesive layer by an alternating current magnetron sputtering method;
forming a nitrogen-doped diamond-like carbon layer on the intermediate layer by an alternating current magnetron sputtering method;
forming a nitrogen and hydrogen-doped diamond-like carbon layer on the nitrogen-doped diamond like carbon layer by an alternating current magnetron sputtering method; and
forming a hydrogen-doped diamond-like carbon layer on the nitrogen and hydrogen-doped diamond like carbon layer by an alternating current magnetron sputtering method.

15. The method as claimed in claim 14, wherein the each of the diamond-like carbon layers comprises graphite or carbon.

16. The method as claimed in claim 14, wherein the adhesive layer comprises chrome, titanium, or chrome titanium.

17. The method as claimed in claim 14, wherein the intermediate layer comprises chromium nitride, titanium nitride, and a mixture thereof.
